(19) United States
(12) Patent Application Publication
(10) Pub. No.: US 2024/0179895 A1
(43) Pub. Date: May 30, 2024

(54) SEMICONDUCTOR DEVICE INCLUDING MEMORY ELEMENTS

(71) Applicant: Unisantis Electronics Singapore Pte. Ltd., Singapore (SG)

(72) Inventors: Nozomu HARADA, Tokyo (JP); Masakazu KAKUMU, Tokyo (JP); Koji SAKUI, Tokyo (JP)

(21) Appl. No.: 18/397,079

(22) Filed: Dec. 27, 2023

(30) Foreign Application Priority Data
Dec. 28, 2022 (WO) PCT/JP2022/048611

(51) Int. Cl. H10B 12/00; H10B 41/30; H10B 41/40; H10B 41/43; H10B 43/30; H10B 43/40

(52) U.S. Cl. CPC H10B 12/50; H10B 12/09; H10B 41/30; H10B 41/40; H10B 41/43; H10B 43/30; H10B 43/40

(57) ABSTRACT

In a semiconductor device including pillar-shaped Players standing erect on Player substrates, a random access memory cell includes a first gate insulating layer and a first gate conductor layer surrounding a lower P layer, a second gate insulating layer surrounding a first Player, a second gate conductor layer, and N⁺ layers at either end of the first Player, a metal oxide semiconductor transistor includes a third gate insulating layer surrounding a second P layer, a third gate conductor layer, and N⁺ layers at either end of the second Player, a read only memory cell includes a memory layer surrounding a third Player, a fourth gate conductor layer, and N⁺ layers at either end of the third Player, and bottom portion positions of the first to third Players are substantially aligned with a single horizontal line.

### CROSS REFERENCE TO RELATED APPLICATIONS

This application claims priority to PCT/JP2022/048611, filed Dec. 28, 2022, the entire content of which is incorporated herein by reference.

### BACKGROUND OF THE INVENTION

### 1. Field of the Invention

The present invention relates to a semiconductor device including memory elements.

### 2. Description of the Related Art

Today, in technical development of large scale integration (LSI), there is a demand for higher integration, higher performance, lower power consumption, and higher functions of semiconductor devices using memory elements.

In an ordinary planar-type metal oxide semiconductor (MOS) transistor, a channel extends in the horizontal direction along an upper surface of a semiconductor substrate. In contrast, a channel of a surrounding gate transistor (SGT) extends in the vertical direction with respect to the upper surface of the semiconductor substrate (see, for example, Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Accordingly, compared to the planar-type MOS transistor, the SGT enables an increase in density of the semiconductor device. High integration can be achieved for, for example, a dynamic random access memory (DRAM) that uses the SGT as a selection transistor to which a capacitor is connected (see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)), a phase change memory (PCM) to which a resistance change element is connected (see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No. 12, December, pp. 2b012b27 (2010)), a resistive random access memory (RRAM, see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and a magneto-resistive random access memory (MRAM) that changes the resistance by changing the direction of magnetic spin with a current (see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)). Furthermore, there are, for example, a capacitorless DRAM memory cell including a single MOS transistor (see, for example, M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)) and a DRAM memory cell including two groove portions in which the carriers are saved and two gate electrodes (see, for example, Md. Hasan Raza Ansari, Nupur Navlakha, Jae Yoon Lee, Seongjae Cho, “Double-Gate Junctionless IT DRAM With Physical Barriers for Retention Improvement”, IEEE Trans, on Electron Devices vol. 67, pp. 1471-1479 (2020)). However, a capacitorless DRAM has a problem in that it is significantly influenced by coupling of a floating body with a gate electrode from a word line so that a sufficient allowance of voltage cannot be obtained. The present application relates to a memory device using a semiconductor element that can be configured only with a MOS transistor without a resistance change element or a capacitor.

### SUMMARY OF THE INVENTION

There is a problem with the capacitorless single-transistor DRAM (gain cell) in a memory device in that the capacitive coupling between the word line and a body including an element in a floating state is large, and, when a potential of the word line oscillates at the time of data reading or data writing, the oscillation is directly transmitted to the body of the semiconductor substrate as noise. As a result, problems of erroneous reading or erroneous rewriting of stored data occur, and it has been difficult to put a capacitorless single-transistor DRAM into practical use. The above-described problems need to be addressed, and the density of DRAM memory cells needs to be increased. Furthermore, there is a problem of how to integrate a complementary metal oxide semiconductor (CMOS) logic circuit, a random access memory (RAM), a read only memory (ROM), and the like onto the same substrate at a low cost.

To address the above-described problems, a semiconductor device including memory elements according to a first aspect of the present invention includes a first memory element, a metal oxide semiconductor transistor, and a second memory element.

The first memory element includes

a first semiconductor pillar that stands erect on a substrate in a vertical direction with respect to the substrate,

a first impurity region continuous with a bottom portion of the first semiconductor pillar,

a first gate insulating layer in contact with a lower portion of the first semiconductor pillar,

a first gate conductor layer in contact with part of or an entirety of the first gate insulating layer,

a first insulating layer that is provided on the first gate conductor layer and that surrounds the first semiconductor pillar,

a second gate insulating layer that is, in the vertical direction, in contact with an upper surface of the first semiconductor pillar above the first gate insulating layer or in contact with the upper surface and both side surfaces continuous with the upper surface,

a second gate conductor layer that covers the second gate insulating layer, and

a second impurity region and a third impurity region provided at either end, in a horizontal direction, of part of the first semiconductor pillar that is not covered with the second gate insulating layer.

The metal oxide semiconductor transistor includes

a second semiconductor pillar that stands erect on the substrate in the vertical direction with respect to the substrate,

a first material layer that is made of an insulative material or a conductive material and that is in contact with a lower portion of the second semiconductor pillar,

a third gate insulating layer that covers, in the vertical direction, an upper surface of the second semiconductor pillar above the first material layer or that covers the upper surface and both side surfaces of the second semiconductor pillar which face each other,

a third gate conductor layer that covers the third gate insulating layer, and

a fourth impurity region and a fifth impurity region provided at either end, in the horizontal direction, of part of the second semiconductor pillar that is not covered with the third gate insulating layer.

The second memory element includes

a third semiconductor pillar that stands erect on the substrate in the vertical direction with respect to the substrate,

a second material layer that includes an insulative material or that partly includes a conductive material and that surrounds a lower portion of the third semiconductor pillar,

a memory layer that includes a signal charge storage layer interposed between insulating layers and that covers, in the vertical direction, an upper surface of the third semiconductor pillar above the second material layer or that covers the upper surface and both side surfaces of the third semiconductor pillar that face each other,

a fourth gate conductor layer that covers the memory layer, and

a sixth impurity layer and a seventh impurity layer provided at either end, in the horizontal direction, of part of the third semiconductor pillar that is not covered with the signal charge storage layer.

A position of an upper surface of the first semiconductor pillar, a position of an upper surface of the second semiconductor pillar, and a position of an upper surface of the third semiconductor pillar are substantially aligned with each other in the vertical direction.

According to a second aspect of the present invention, in the first aspect, a position of an upper surface of the first insulating layer, a position of an upper surface of the first material layer, and a position of an upper surface of the second material layer are substantially aligned with each other in the vertical direction.

According to a third aspect of the present invention, in the first aspect, a position of a bottom portion of a first semiconductor layer, a position of a bottom portion of a second semiconductor layer, and a position of a bottom portion of a third semiconductor layer are substantially aligned with each other in the vertical direction.

According to a fourth aspect of the present invention, in the first aspect, one or both of the first material layer and the second material layer are formed of an insulative material.

According to a fifth aspect of the present invention, in the first aspect, one or both of the first material layer and the second material layer are formed of a conductive material.

According to a sixth aspect of the present invention, in the first aspect, the signal charge storage layer is formed by a conductive layer of a semiconductor, metal, an alloy, or another conductor, or an insulating layer.

According to a seventh aspect of the present invention, in the first aspect, a transistor including an upper portion of the first semiconductor pillar, the second gate insulating layer, the second gate conductor layer, the second impurity region, and the third impurity region of the first memory element is of a planar type, a transistor including an upper portion of the second semiconductor pillar, the third gate insulating layer, the third gate conductor layer, the fourth impurity region, and the fifth impurity region of the metal oxide semiconductor transistor is of the planar type, and a transistor including an upper portion of the third semiconductor pillar, the memory layer, the fourth gate conductor layer, the sixth impurity layer, and the seventh impurity layer of the second memory element is of the planar type.

According to an eighth aspect of the present invention, in the first aspect, a transistor including an upper portion of the first semiconductor pillar, the second gate insulating layer, the second gate conductor layer, the second impurity region, and the third impurity region of the first memory element is of a planar type, a transistor including an upper portion of the second semiconductor pillar, the third gate insulating layer, the third gate conductor layer, the fourth impurity region, and the fifth impurity region of the metal oxide semiconductor transistor is of a fin type, and a transistor including an upper portion of the third semiconductor pillar, the signal charge storage layer, the fourth gate conductor layer, the sixth impurity layer, and the seventh impurity layer of the second memory element is of the planar type.

According to a ninth aspect of the present invention, in the first aspect, the first impurity region is continuous with a bottom portion of a semiconductor pillar of another first memory element adjacent to the first semiconductor pillar.

According to a tenth aspect of the present invention, in the first aspect, the first impurity region is separate from an impurity layer of a bottom portion of a semiconductor pillar of another first memory element adjacent to the first semiconductor pillar.

According to an eleventh aspect of the present invention, in the first aspect, an eighth impurity layer is provided at a bottom portion of one or each of the second semiconductor pillar and the third semiconductor pillar.

According to a twelfth aspect of the present invention, in the first aspect, the first gate conductor layer is divided into two conductor layers in one or both of the horizontal direction and the vertical direction, and the divided conductor layers are driven in a synchronous manner or in an asynchronous manner.

According to a thirteenth aspect of the present invention, in the first aspect, the second impurity region, the third impurity region, the first gate conductor layer, and the second gate conductor layer are configured to perform a memory write operation and a memory erase operation. In the memory write operation, voltages applied to the second impurity region, the third impurity region, the first gate conductor layer, and the second gate conductor layer are controlled so as to generate an electron group and a positive hole group in an upper portion of the first semiconductor pillar by using impact ionization caused by a current flowing between the first impurity region and the second impurity region or by using a gate-induced drain-leakage current, and part or an entirety of the electron group or the positive hole group that is a majority carrier out of the generated electron group and the generated positive hole group is caused to remain in the first semiconductor pillar mainly surrounded by the first gate insulating layer.

In the memory erase operation, the electron group or the positive hole group that is the majority carrier having been caused to remain is removed from a subset or all of the first impurity region, the second impurity region, and the third impurity region.

### BRIEF DESCRIPTION OF THE DRAWINGS

FIG. 1 is a diagram for explaining the structure of a random access memory (RAM) device using a semiconductor element according to an embodiment.

FIG. 2A, FIG. 2B, and FIG. 2C are diagrams for explaining a data write operation of the RAM device using the semiconductor element according to the embodiment.

FIG. 3A, FIG. 3B, and FIG. 3C are diagrams for explaining a data erase operation of the RAM device using the semiconductor element according to the embodiment.

FIG. 4AA, FIG. 4AB, and FIG. 4AC are diagrams for explaining the structures of a RAM cell, a read only memory (ROM) cell, and a metal oxide semiconductor (MOS) transistor of a logic circuit formed on the same substrate according to the present embodiment.

FIG. 4BA, FIG. 4BB, and FIG. 4BC are diagrams for explaining the structures of the RAM cell, the ROM cell, and the MOS transistor of the logic circuit formed on the same substrate according to the present embodiment.

FIG. 5AA, FIG. 5AB, and FIG. 5AC are diagrams for explaining a method for manufacturing in which the RAM cell, the ROM cell, and the MOS transistor of the logic circuit are formed on the same substrate according to the present embodiment.

FIG. 5BA, FIG. 5BB, and FIG. 5BC are diagrams for explaining the method for manufacturing in which the RAM cell, the ROM cell, and the MOS transistor of the logic circuit are formed on the same substrate according to the present embodiment.

FIG. 5CA, FIG. 5CB, and FIG. 5CC are diagrams for explaining the method for manufacturing in which the RAM cell, the ROM cell, and the MOS transistor of the logic circuit are formed on the same substrate according to the present embodiment.

FIG. 5DA, FIG. 5DB, and FIG. 5DC are diagrams for explaining the method for manufacturing in which the RAM cell, the ROM cell, and the MOS transistor of the logic circuit are formed on the same substrate according to the present embodiment.

FIG. 5EA, FIG. 5EB, and FIG. 5EC are diagrams for explaining the method for manufacturing in which the RAM cell, the ROM cell, and the MOS transistor of the logic circuit are formed on the same substrate according to the present embodiment.

FIG. 5FA, FIG. 5FB, and FIG. 5FC are diagrams for explaining the method for manufacturing in which the RAM cell, the ROM cell, and the MOS transistor of the logic circuit are formed on the same substrate according to the present embodiment.

FIG. 5GA, FIG. 5GB, and FIG. 5GC are diagrams for explaining the method for manufacturing in which the RAM cell, the ROM cell, and the MOS transistor of the logic circuit are formed on the same substrate according to the present embodiment.

FIG. 5HA, FIG. 5HB, and FIG. 5HC are diagrams for explaining the method for manufacturing in which the RAM cell, the ROM cell, and the MOS transistor of the logic circuit are formed on the same substrate according to the present embodiment.

FIG. 5IA, FIG. 5IB, and FIG. 5IC are diagrams for explaining the method for manufacturing in which the RAM cell, the ROM cell, and the MOS transistor of the logic circuit are formed on the same substrate according to the present embodiment.

### DESCRIPTION OF THE PREFERRED EMBODIMENTS

Hereinafter, a memory device using a semiconductor element and a method for manufacturing the memory device according to an embodiment of the present invention will be described with reference to the drawings.

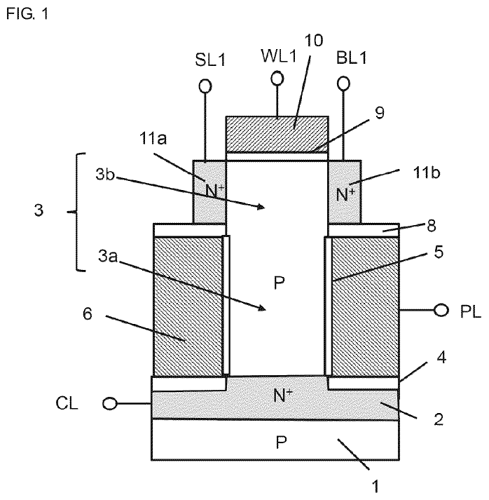

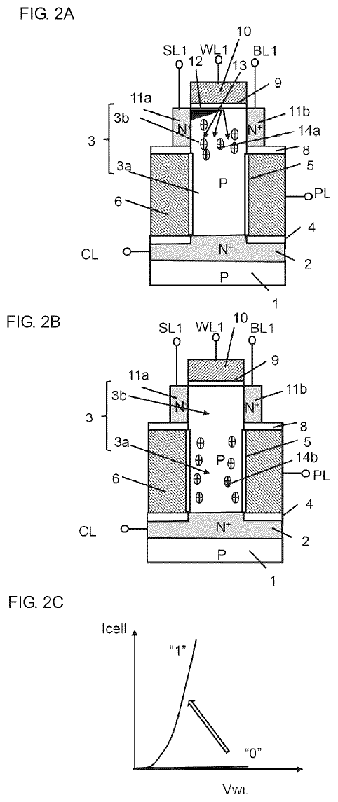

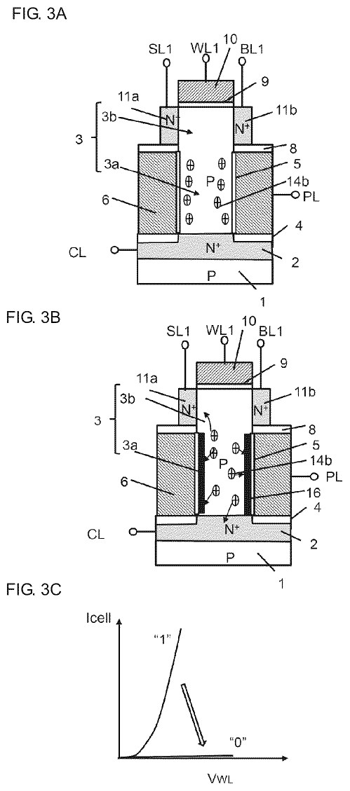

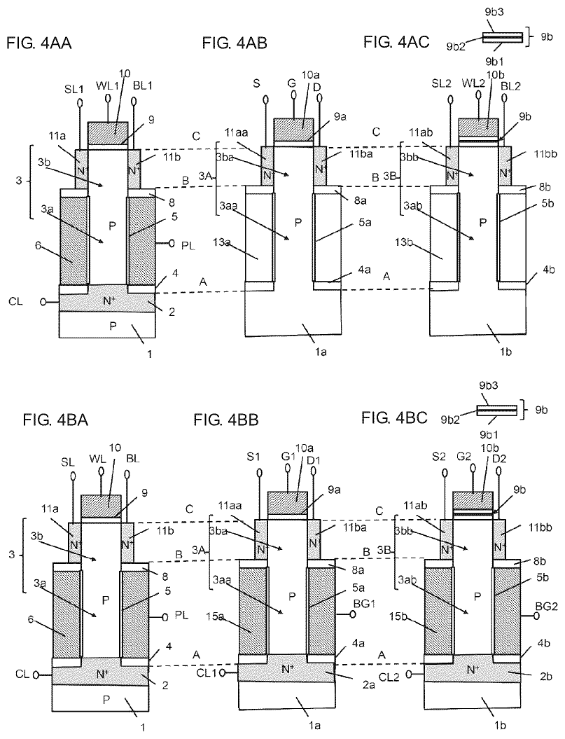

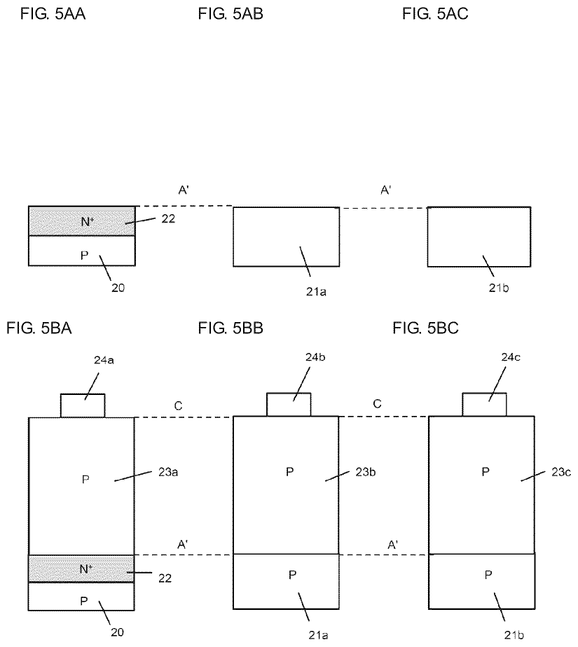

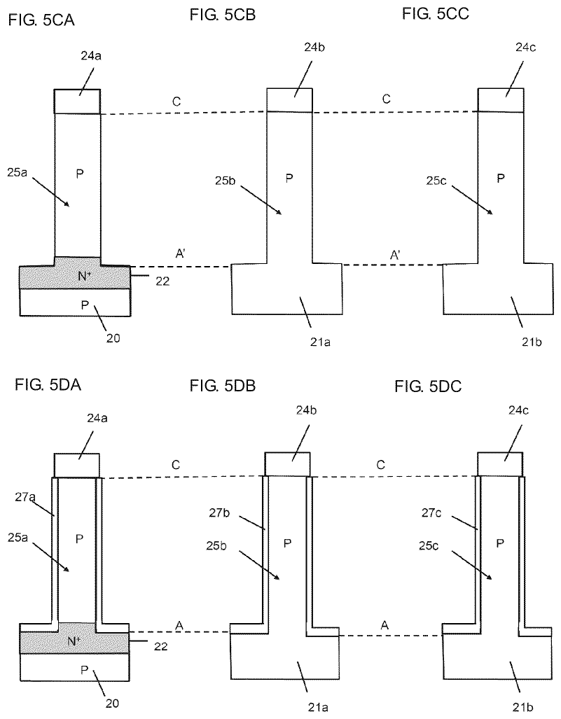

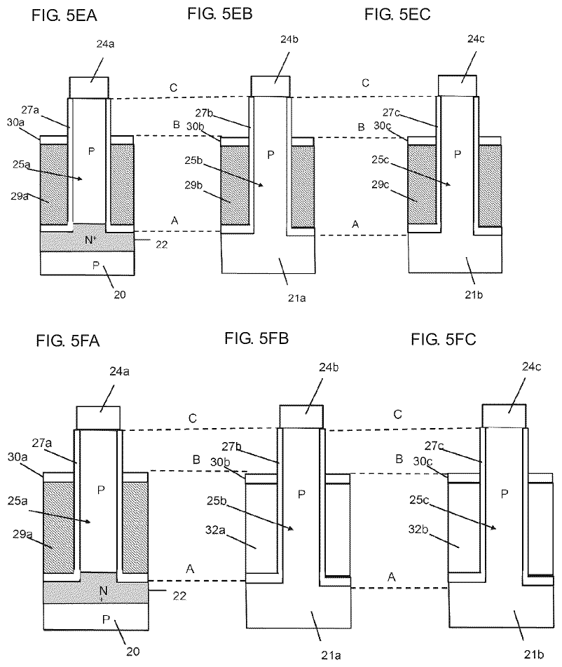

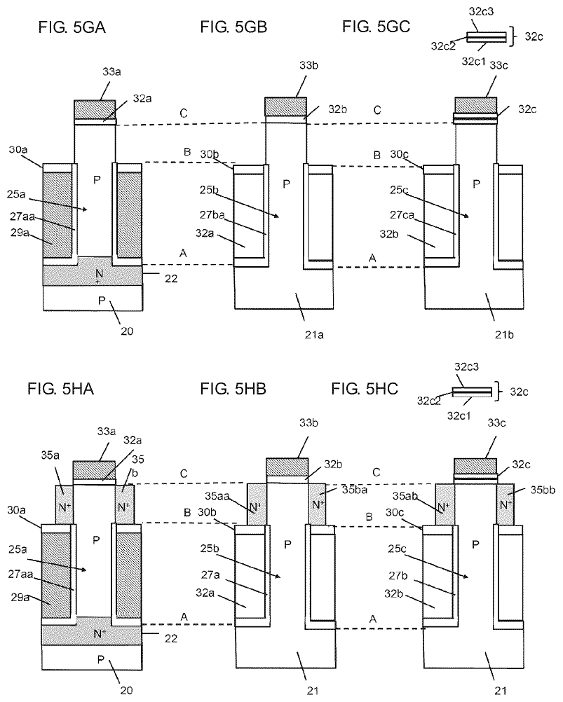

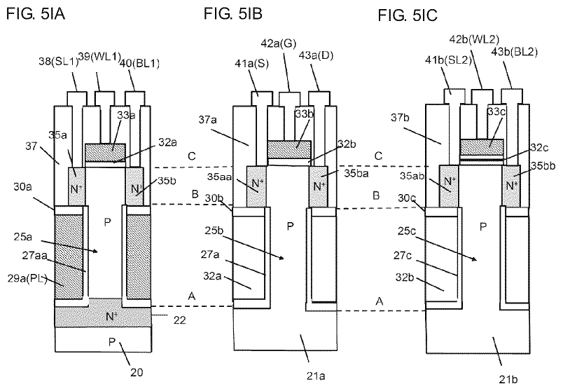

The structure of a random access memory (hereinafter referred to as a RAM) cell according to the present embodiment is described with reference to FIG. 1. A data write mechanism of the RAM cell according to the present embodiment is described with reference to FIGS. 2A to 2C. A data erase mechanism of the RAM cell according to the present embodiment is described with reference to FIGS. 3A to 3C. The structures of a RAM cell, a read only memory (hereinafter referred to as a ROM) cell, and a metal oxide semiconductor transistor (a MOS field effect transistor, hereinafter referred to as a “MOS transistor”) of a logic circuit formed on the same substrate and disposed on the same substrate according to the present invention are described with reference to FIGS. 4AA to 4BC. In addition, a method for manufacturing the RAM cell, the ROM cell, and the MOS transistor of the logic circuit formed on the same substrate according to the present embodiment illustrated in FIG. 4A is described with reference to FIGS. 5AA to 5IC.

FIG. 1 illustrates a vertical sectional structure of the RAM cell according to the embodiment of the present invention. An N⁺ layer 2 (serving as an example of a “first impurity region” according to the present invention. Hereinafter, a semiconductor region including a donor impurity at a high concentration is referred to as an “N⁺ layer”) is disposed on a Player substrate 1 (serving as an example of a “substrate” according to the present invention). A pillar-shaped Player 3 (serving as an example of a “first semiconductor pillar” according to the present invention) is provided. The pillar-shaped P layer 3 includes a pillar-shaped Player 3 including an acceptor impurity and an upper layer of the N⁺ layer 2. The pillar-shaped Player 3 has a rectangular horizontal section and a rectangle vertical section. An insulating layer 4 is provided so as to cover an upper surface of the N⁺ layer 2 at an outer peripheral portion of the pillar-shaped Player 3 in plan view. A first gate insulating layer 5 (serving as an example of a “first gate insulating layer” according to the present invention) is provided so as to cover a lower portion of the pillar-shaped Player 3. A first gate conductor layer 6 (serving as an example of a “first gate conductor layer” according to the present invention) is provided so as to surround the first gate insulating layer 5. A first insulating layer 8 (serving as an example of a “first insulating layer” according to the present invention) is provided on the first gate insulating layer 5 and the first gate conductor layer 6. A pillar-shaped Player 3a covered with the first gate insulating layer 5 and a pillar-shaped P layer 3b provided on the pillar-shaped P layer 3a constitute the pillar-shaped Player 3. An N⁺ layer 11a (serving as an example of a “second impurity region” according to the present invention) including a donor impurity at a high concentration is provided on one side of the pillar-shaped Player 3b of the page. An N⁺ layer 11b (serving as an example of a “third impurity region” according to the present invention) is provided on another side of the page that is a side opposite from the side where the N⁺ layer 11a is provided. A second gate insulating layer 9 (serving as an example of a “second gate insulating layer” according to the present invention) is provided so as to cover an upper surface of the pillar-shaped Player 3b. A second gate conductor layer 10 (serving as an example of a “second gate conductor layer” according to the present invention) is provided so as to cover the second gate insulating layer 9.

The N⁺ layer 11a is connected to a first source line SL1, the N⁺ layer 11b is connected to a first bit line BL1, the second gate conductor layer 10 is connected to a first word line WL1, the first gate conductor layer 6 is connected to a plate line PL, and the N⁺ layer 2 is connected to a control line CL. Memory operation is performed by operating potentials of the first source line SL1, the first bit line BL1, the first plate line PL1, and the first word line WL1. In an actual memory device, many RAM cells described above are two-dimensionally arranged on the Player substrate 1.

Referring to FIG. 1, although the Player substrate 1 is defined as a P-type semiconductor, a concentration distribution of the impurity may exist in the Player substrate 1. Also, a concentration distribution of the impurity may exist in the N⁺ layer 2 and the pillar-shaped Player 3. Furthermore, the concentrations of impurity set for the pillar-shaped Players 3a and 3b may be different from each other.

Furthermore, referring to FIG. 1, the N⁺ layer 2 is connected to the control line CL. In this case, the N⁺ layer 2 is continuous with an N⁺ layer 2 of an adjacent memory cell. However, the N⁺ layer 2 may be formed only at a bottom portion of the pillar-shaped Player 3.

Furthermore, the N⁺ layer 11a and the N⁺ layer 11b may be formed of a P⁺ layer in which positive holes are a majority carrier (hereinafter, a semiconductor region including an acceptor impurity at a high concentration is referred to as a “P⁺ layer”) so as to operate the memory with electrons used as the carrier for writing. In this case, preferably, materials are selected such that a work function of the first gate conductor layer 6 is lower than a work function of the second gate conductor layer 10.

Furthermore, referring to FIG. 1, for example, a P-well structure or a silicon on insulator (SOI) substrate may be used for the Player substrate 1.

Furthermore, the insulating layer 4 illustrated in FIG. 1 may be integrally formed with the first gate insulating layer 5.

Furthermore, the first gate conductor layer 6 and the second gate conductor layer 10 may be conductor layers such as a semiconductor layers doped with metal or an alloy at a high concentration. Furthermore, a plurality of conductor layers may constitute the first gate conductor layer 6 and the second gate conductor layer 10. Preferably, the work function of the second gate conductor layer 10 is lower than the work function of the first gate conductor layer 6.

Referring to FIGS. 2A to 2C, a data write operation of the RAM cell according the embodiment of the present invention is described. For example, polysilicon including many acceptor impurities at a higher concentration (hereinafter, polysilicon including acceptor impurities at a higher concentration is referred to as “P⁺ poly”) is used for the first gate conductor layer 6 connected to the plate line PL. Polysilicon including many donor impurities at a higher concentration (hereinafter, polysilicon including donor impurities at higher concentration is referred to as “N⁺ poly”) is used for the second gate conductor layer 10 connected to the word line WL. As illustrated in FIG. 2A, the MOS transistor in this memory cell operates with the following layers as components: the N⁺ layer 11a serving as the source, the N⁺ layer 11b serving as the drain, the second gate insulating layer 9 serving as a gate insulating layer, the second gate conductor layer 10 serving as a gate, and the pillar-shaped Player 3b serving as a channel. For example, 0 V is applied to the Player substrate 1, 0 V is input to the N⁺ layer 11a connected to the first source line SL1, 3 Vis input to the N⁺ layer 11b connected to the first bit line BL1, 0V is input to the first gate conductor layer 6 connected to the plate line PL, and 1.5V is input to the second gate conductor layer 10 connected to the first word line WL1. A partial inversion layer 12 is formed in the pillar-shaped Player 3b immediately below the gate second insulating layer 9 underlying the gate conductor layer 10, and a pinch-off point 13 exists. In this case, the MOS transistor including the second gate conductor layer 10 operates in a saturation region.

As a result, in the MOS transistor including the second gate conductor layer 10, an electric field is maximized between a pinch-off point 13 and a boundary region of the N⁺ layer 11b, thereby impact ionization is produced in this region. Due to this impact ionization, electrons accelerated from the N⁺ layer 11a connected to the first source line SL1 toward the N⁺ layer 11b connected to the first bit line BL1 impact an Si lattice, and electron-positive hole pairs are generated by kinetic energy of the electrons. Generated positive holes 14a spread, due to a concentration gradient thereof, toward a region where a positive hole concentration is lower. Furthermore, although part of generated electrons flows to the second gate conductor layer 10, most of the generated electrons flow to the N⁺ layer 11b connected to the first bit line BL1. Instead of producing the above-described impact ionization, a gate-induced drain-leakage (GIDL) current may be caused to flow to generate a positive hole group 14b. (see, for example, E. Yoshida, T, Tanaka, “A Capacitorless 1T-DRAM Technology Using Gate-Induced Drain-Leakage (GIDL) Current for Low-Power and High-Speed Embedded Memory”, IEEE Trans, on Electron Devices vol. 53, pp. 692-697 (2006)).

FIG. 2B illustrates a positive hole group 14b stored in the pillar-shaped Player 3a when the first word line WL1, the first bit line BL1, the plate line PL, and the first source line SL1 become 0 V immediately after data writing. At an initial stage, the concentration of the generated positive holes increases in a region of the pillar-shaped Player 3b, and positive holes move, through spreading, toward the pillar-shaped Player 3a due to the concentration gradient. Furthermore, since a P⁺ poly having a higher work function than the work function of the N⁺ poly is used for the first gate conductor layer 6, the positive hole group 14b is stored at a higher concentration near the first gate insulating layer 5 in the pillar-shaped Player 3a. As a result, the positive hole concentration in the pillar-shaped Player 3a becomes higher than the positive hole concentration in the pillar-shaped Player 3b. Since the pillar-shaped Player 3a and the pillar-shaped Player 3b are electrically connected to each other, the pillar-shaped Player 3a that is substantially a substrate of the MOS transistor including the gate conductor layer 10 is charged to a positive bias. Furthermore, although the positive hole group 14b moves toward the N⁺ layers 11a and 11b or the N⁺ layer 2 and is gradually recombined with the electrons, a threshold voltage of the MOS transistor including the second gate conductor layer 10 reduces due to a positive substrate bias effect produced by the positive hole group 14b stored in the pillar-shaped Player 3a. As illustrated in FIG. 2C, this reduces the threshold voltage of the MOS transistor including the second gate conductor layer 10 connected to the first word line WL1. This write state is assigned to logical storage data “1”. The conditions of the voltage applied to the first bit line BL1, the first source line SL1, the first word line WL1, and the plate line PL described above are examples for performing the write operation and may be other conditions of the voltage under which the write operation can be performed.

Furthermore, referring to FIGS. 2A to 2C, a combination of P⁺ poly (work function of 5.15 eV) and N⁺ poly (work function of 4.05 eV) is described as an example of a combination of the first gate conductor layer 6 and the second gate conductor layer 10. However, the combination may include metal, metal nitride, an alloy of metal or metal nitride (including silicide), or a laminated structure such as Ni (work function of 5.2 eV) and N⁺ poly, Ni and W (work function of 4.52 eV), Ni and TaN (work function of 4.0 eV)/W/TiN (work function of 4.7 eV). Alternatively, the first gate conductor layer 6 and the second gate conductor layer 10 may be formed by the same conductor layer with different drive voltages applied thereto for performing the data write operation. For example, in a state of data holding as described above, a similar effect can be obtained also when the first gate conductor layer 6 and the second gate conductor layer 10 which have the same work function are used, 0 V is applied to the first bit line BL1, the first word line WL1, and the first source line SL1, and −0.5 V is applied to the plate line PL.

Next, referring to FIGS. 3A to 3C, a mechanism of a data erase operation is described. FIG. 3A illustrates a state immediately after the positive hole group 14b generated due to the impact ionization in a previous cycle and stored is stored mainly in the pillar-shaped Player 3a before the data erase operation. As illustrated in FIG. 3B, in the erase operation, a negative voltage VERA is applied to the first source line SL1. Furthermore, the voltage of the plate line PL is set to 2 V. Here, VERA is, for example, −0.5 V. As a result, independently of an initial potential of the pillar-shaped Player 3a, a P-N junction between the pillar-shaped Player 3b and the N⁺ layer 11a to which the first source line SL1 is connected and which serves as the source is brought into a forward bias state. As a result, the positive hole group 14b generated due to the impact ionization in the previous cycle and stored mainly in the pillar-shaped Player 3a moves to the N⁺ layer 11a connected to the first source line SL1. Furthermore, as a result of application of the voltage of 2 V to the plate line PL, an inversion layer 16 is formed at an interface between the first gate insulating layer 5 and the pillar-shaped Player 3a and brought into contact with the N⁺ layer 2. Accordingly, the positive holes 14a stored in the pillar-shaped Player 3a flow from the pillar-shaped Player 3a to the N⁺ layer 2 and the inversion layer 16 and are recombined with the electrons. As a result, the positive hole concentration of the pillar-shaped Player 3a reduces over time, and the threshold voltage of the MOS transistor increases relative to the value at the time of writing “1” and is returned to the initial state. Accordingly, as illustrated in FIG. 3C, the threshold of the MOS transistor including the second gate conductor layer 10 to which the first word line WL1 is connected is restored to the initial threshold. An erase state of this memory is set to logical storage data “0”. At this time of data erase, to reliably perform the data erase operation, the area of the recombination of the electrons and the positive holes is substantially increased relative to that at the time of data accumulation.

Furthermore, for example, when 2 V is applied to the plate line PL at the time of data erase, the N⁺ layer 11a, the N⁺ layer 11b, and the N⁺ layer 2 can be electrically connected by using the inversion layer 16, and thereby time for erasing data can be reduced.

The conditions of the voltage applied to the first bit line BL1, the first source line SL1, the first word line WL1, and the plate line PL described above are examples for performing the erase operation and may be other conditions of the voltage under which the erase operation can be performed. For example, although an example in which the first gate conductor layer 6 is biased to 2 V has been described above, an inversion layer in which the electrons are the majority carriers can be formed at an interface between the pillar-shaped Player 3a and the first gate insulating layer 5 and an interface between the pillar-shaped Player 3b and the second gate insulating layer 9 when, for example, the first bit line BL1 is biased to 0.2 V, the first source line SL1 is biased to 0 V, and the first and second gate conductor layers 6 and 10 are biased to 2V at the time of erase. Accordingly, the recombination area of the electrons and the positive holes can be increased, and further, the erase time can be more positively reduced by flowing a current in which the electrons are the majority carrier between the first bit line BL1 and the first source line SL1. A data read operation may be performed by using a MOS transistor operation or a bipolar transistor operation.

The structure and the operation mechanism of the present embodiment have the following features.

(1) Since the pillar-shaped Player 3b of the MOS transistor including the second gate conductor layer 10 connected to the first word line WL1 is electrically connected to the pillar-shaped Player 3a, the capacitance for storing the generated positive hole group 14b can be freely changed by adjusting the volume of the pillar-shaped Player 3a. That is, in order to increase holding time, for example, it is sufficient that the depth of the pillar-shaped Player 3a be increased. Accordingly, the characteristics for holding the storage data are improved.

(2) Furthermore, it is allowed to intentionally reduce, compared to the volume of the pillar-shaped P layer 3a in which the positive hole group 14b serving as signals is mainly stored, the area by which the N⁺ layer 2, N⁺ layer 11a, and the N⁺ layer 11b involved in the recombination with the electrons are in contact with each other. Accordingly, the recombination of the positive holes 14a being signal charges with the electrons can be suppressed, and the holding time to hold the stored positive hole group 14b can be increased.

(3) Furthermore, since P⁺ poly is used for the first gate conductor layer 6, the stored positive holes 14a are stored near the interface of the pillar-shaped Player 3a in contact with the first gate insulating layer 5. Accordingly, the positive hole group 14b can be stored at a position apart from contact portions of the N⁺ layer 11a and the N⁺ layer 11b with the pillar-shaped Player 3b which serve as P-N junction portions and from which the recombination of the electrons and the positive holes is originated. Thus, a stable positive hole group 14b can be stored. Accordingly, as this RAM element, the effect of substrate bias is improved, the time to hold memory is increased, and an allowance of the operating voltage for write is increased. As illustrated in FIGS. 3A to 3C, in the data erase operation, the area of the recombination of the electrons and the positive holes is substantially increased at the time of data erase relative to that at the time of data accumulation. This allows obtaining of a stable state of the logical information data “0” in a short time. Thus, an operating speed of the memory element is improved.

(4) According to the present embodiment, the pillar-shaped Player 3a is electrically connected to the Player substrate 1 and the N⁺ layer 2. Furthermore, the potential of the pillar-shaped Player 3a can be controlled with the voltage applied to the first gate conductor layer 6. Accordingly, in either the data write operation or the erase operation, for example, a semiconductor portion below the second gate insulating layer 9 is not entirely depleted or the substrate bias does not become unstable due to a floating state during operation of the MOS transistor unlike a case with the SOI structure. Thus, the threshold, drive current, and so forth of the MOS transistor are unlikely to be influenced by an operation status. Accordingly, regarding the characteristics of the MOS transistor, the voltages related to desired memory operations can be set in a wide range by adjusting the thickness, the type of the impurity, the concentration of the impurity, and a profile of the pillar-shaped Player 3b, the concentration of the impurity and a profile of the pillar-shaped Player 3, the thickness and the material of the gate insulating layer 9, and the work functions of the second gate conductor layer 10 and the first gate conductor layer 6. Furthermore, since the portion below the MOS transistor is not completely depleted and a depleted layer spreads in the depth direction of the pillar-shaped Player 3b, there is little influence due to coupling of a floating body with a gate electrode from the word line, which is a drawback of a capacitorless DRAM. That is, according to the present embodiment, allowance of the operating voltage of the memory can be increased in the design.

(5) The present embodiment also produces an effect of suppressing malfunction of the RAM cell. In an operation of the RAM cell, there is a significant problem in that, when a voltage operation is performed on a target cell, an unnecessary voltage is applied to a subset of electrodes of a nontarget cell disposed in an RAM cell array, leading to malfunctioning (see, for example, Takashi Ohasawa and Takeshi Hamamoto, “Floating Body Cell—a Novel Body Capacitorless DRAM Cell”, Pan Stanford Publishing (2011)). That is, as a phenomenon, this means that a cell to which “1” has been written is set to “0” due to another cell operation or a cell to which “0” has been written is set to “1” due to another cell operation (hereinafter, a phenomenon caused by this malfunction is represented as a disturb defect). According to the present embodiment, in the case where “1” is originally written as data information, the amount of the stored positive hole group 14b can be increased by adjusting the depth of the pillar-shaped Player 3a compared to the amount of recombination of the electrons and the positive holes caused by the transistor operation. Thus, under a condition that would cause the disturb defect in the related-art memory, smaller influence is exerted on the fluctuation of the threshold of the MOSFET, and accordingly, the defect is unlikely to occur. Furthermore, in the case where “0” is originally written as the data information, even when the positive holes are unintentionally generated due to the transistor operation in reading, the positive holes immediately spread to the pillar-shaped Player 3a. Thus, when the depth of the pillar-shaped Player 3a is increased as in the former case, there is a small rate of change in the concentration of the positive holes in the entirety of the pillar-shaped Player 3a and the pillar-shaped Player 3b. Also in this case, influence on the threshold of the MOSFET is small, and the probability of the disturb defect being caused can be reduced. Thus, according to the present embodiment, the structure is resistant to the disturb defect.

(6) When the present RAM cell is seen in plan view, a single memory cell region is a single MOS transistor including the second gate insulating layer 9, the second gate conductor layer 10, the pillar-shaped Player 3b, the N⁺ layer 11a, and the N⁺ layer 11b. That is, the area of the memory cell is not increased by a signal storage section that holds the positive holes 14a being the signal charges and that is formed by the first gate conductor layer 6, the first gate insulating layer 5, the pillar-shaped Player 3a, and the N⁺ layer 11a. Thus, the RAM cell is highly integrated.

Referring to FIGS. 4AA to 4AC, structures of the RAM cell, an N-channel MOS transistor of the logic circuit, and the ROM cell according to the present embodiment formed on the same substrate are described. FIG. 4AA illustrates the sectional structure of the RAM cell. FIG. 4AB illustrates the sectional structure of the N-channel MOS transistor of the logic circuit formed on the same substrate as that of the RAM cell. FIG. 4AC illustrates the sectional structure of the ROM cell formed on the same substrate as that of the RAM cell. In FIGS. 4AA to 4AC, the same structural portions as those of FIG. 1 are denoted by the same reference numerals.

The structure of the RAM cell (serving as an example of a “first memory element” according to the present invention) illustrated in FIG. 4AA is the same as that of FIG. 1. Referring to FIG. 4AB, a pillar-shaped Player 3A (serving as an example of a “second semiconductor pillar” according to the present invention) that stands erect in the vertical direction is provided on a Player substrate 1a continuous with the Player substrate 1 (serving as the example of the “substrate” according to the present invention). The pillar-shaped Player 3A has a rectangular shape in plan view. An insulating layer 5a is provided so as to surround a pillar-shaped Player 3aa provided in a lower portion of the pillar-shaped Player 3A. A first material layer (serving as an example of a “first material layer” according to the present invention) is formed by, from below, an insulating layer 4a (serving as an example of a “second insulating layer” according to the present invention), an insulating layer 13a (serving as an example of a “first intermediate material layer” according to the present invention), and an insulating layer 8a (serving as an example of a “fourth insulating layer” according to the present invention) so as to surround the insulating layer 5a. A third gate insulating layer 9a (serving as an example of a “third gate insulating layer” according to the present invention) is provided so as to cover an upper surface of a pillar-shaped P layer 3ba in an upper portion of the pillar-shaped Player 3A. A third gate conductor layer 10a (serving as an example of a “third gate conductor layer” according to the present invention) is provided so as to cover the third gate insulating layer 9a. An N⁺ layer 11aa (serving as an example of a “fourth impurity region” according to the present invention) and an N⁺ layer 11ba (serving as an example of a “fifth impurity region” according to the present invention) are provided at either end of the pillar-shaped Player 3ba. Thus, the N-channel MOS transistor of the logic circuit (serving as an example of a “MOS transistor” according to the present invention) is formed. In the vertical direction, the position of a surface of the Player substrate 1a at an outer peripheral portion of the pillar-shaped Player 3A is substantially coincident with the position of a surface of the N⁺ layer 2 at an outer peripheral portion of the pillar-shaped Player 3 at line A. In the vertical direction, the position of a surface of the insulating layer 8a is substantially coincident with the position of a surface of the first insulating layer 8 at line B. In the vertical direction, the position of a surface of a top portion of the pillar-shaped P layer 3A is substantially coincident with the position of a surface of a top portion of the pillar-shaped Player 3 at line C. In the case where the MOS transistor including the N⁺ layers 11a and 11b, the second gate insulating layer 9, the second gate conductor layer 10, and the pillar-shaped Player 3b of the channel of the RAM cell is of a planar type and the MOS transistor including the N⁺ layers 11aa and 11ba, the third gate insulating layer 9a, the third gate conductor layer 10a, and the pillar-shaped Player 3ba of the channel of the logic circuit is of a fin type, an upper surface of the pillar-shaped Player 3ba is formed at a position higher than the position of an upper surface of the pillar-shaped Player 3b with reference to the position of line B. Furthermore, with reference to the position of line B, the position of a bottom portion of the pillar-shaped Player 3 of the RAM cell and the position of a bottom portion of the pillar-shaped Player 3A of the MOS transistor may be different from each other.

As illustrated in FIG. 4AC, a pillar-shaped Player 3B (serving as an example of a “third semiconductor pillar” according to the present invention) that stands erect in the vertical direction and has a rectangular shape in plan view is provided on a Player substrate 1b continuous with the Player substrates 1 and 1a. An insulating layer 5b is provided so as to surround a pillar-shaped Player 3ab provided in a lower portion of the pillar-shaped Player 3B. A second material layer (serving as an example of a “second material layer” according to the present invention) is formed by, from below, an insulating layer 4b (serving as an example of a “fifth insulating layer” according to the present invention), an insulating layer 13b (serving as an example of a “second intermediate material layer” according to the present invention), and an insulating layer 8b (serving as an example of a “sixth insulating layer” according to the present invention) so as to surround the insulating layer 5b. A memory layer 9b (serving as an example of a “memory layer” according to the present invention) formed by an insulating layer 9b1, a signal charge storage layer 9b2 (serving as an example of a “signal charge storage layer” according to the present invention), and an insulating layer 9b3 is provided so as to cover an upper surface of a pillar-shaped Player 3bb in an upper portion of the pillar-shaped P layer 3B (only the memory layer 9b is extracted and indicated in an upper portion of FIG. 4AC). A fourth gate conductor layer 10b (serving as an example of a “fourth gate conductor layer” according to the present invention) is provided so as to cover the memory layer 9b. An N⁺ layer 11ab (serving as an example of a “sixth impurity layer” according to the present invention) and an N⁺ layer 11bb (serving as an example of a “seventh impurity layer” according to the present invention) are provided at either end of the pillar-shaped P layer 3bb. Thus, the ROM cell (serving as an example of a “second memory element” according to the present invention) is formed. The position of a surface of the Player substrate 1b at an outer peripheral portion of the pillar-shaped P layer 3B is substantially coincident with the position of the surface of the N⁺ layer 2 at the outer peripheral portion of the pillar-shaped Player 3 at line A. In the vertical direction, the position of a surface of the insulating layer 8b is substantially coincident with the position of the surface of the first insulating layer 8 at line B. In the vertical direction, the position of a surface of a top portion of the pillar-shaped Player 3B is substantially coincident with the position of the surface of a top portion of the pillar-shaped Player 3 at line C. Furthermore, with reference to the position of line B, one or both of a position of the top portion and a position of the bottom portion of the pillar-shaped Player 3B may be different from those of the pillar-shaped P layer 3. The signal charge storage layer 9b2 may be, for example, a floating conductive layer formed of a semiconductor, a conductor, an alloy, or the like or a charge trap insulating layer formed of silicon nitride (SiN) or the like. The insulating layer 9b1 may be a thin insulating layer such as a tunnel SiO₂ layer.

The third gate conductor layer 10a is connected to a gate line G, the N⁺ layer 11aa is connected to a source line S, and the N⁺ layer 11ba is connected to a drain line D. The fourth gate conductor layer 10b is connected to a second word line WL2, the N⁺ layer 11ab is connected to a second source line SL2, and the N⁺ layer 11bb is connected to a second bit line BL2. Thus, the RAM cell, the N-channel MOS transistor of the logic circuit, and the ROM cell are formed on the Player substrates 1, 1a, and 1b continuous with each other. In the actual logic circuit, a P-channel MOS transistor is formed on the P layer substrate 1a that is the same as that of the N-channel MOS transistor. Although this P-channel MOS transistor is different from the N-channel MOS transistor in that, for example, the N⁺ layers 11aa and 11ba are replaced with P⁺ layers and an isolated N well is formed on the Player substrate 1a in the P-channel MOS transistor, a basic structure of the P-channel MOS transistor is same as that of the N-channel MOS transistor illustrated in FIG. 4AB, and the positional relationships in the vertical direction of the P-channel MOS transistor are the same as those of the N-channel MOS transistor. Furthermore, the concentration of the donor impurity of the isolated N well may be set to be the same as that of the N⁺ layer 2 so as to simplify manufacturing steps. Impurity layers to be served as wells may be provided in the pillar-shaped Player 3A of the N-channel MOS transistor illustrated in FIG. 4AB, in a bottom portion of the pillar-shaped Player 3B of the ROM cell illustrated in FIG. 4AC, and in upper portions of the Player substrates 1a and 1b.

Each of the insulating layers 4a, 5a, 8a, and 13a may be formed of a corresponding one of materials that are different from each other. The insulating layer 4 and the first gate insulating layer 5 are formed of the same material and continuous with each other. Likewise, the insulating layer 4a and the insulating layer 5a are formed of the same material and continuous with each other, and the insulating layer 4b and the insulating layer 5b are formed of the same material and continuous with each other. Furthermore, the insulating layers 13a and 8a are formed of the same material and continuous with each other. Likewise, the insulating layers 13b and 8b are formed of the same material and continuous with each other. Neither the insulating layers 5a nor 5b is necessarily provided.

The differences in structure between the RAM cell illustrated in FIG. 4AA, the N-channel MOS transistor illustrated in FIG. 4AB, and the ROM cell illustrated in FIG. 4AC are as follows.

(1) The N⁺ layer 2 provided in the RAM cell is not provided in the N-channel MOS transistor of the logic circuit or the ROM cell.

(2) The insulating layers 13a and 13b are respective provided in the N-channel MOS transistor and the ROM cell at portions corresponding to the first gate conductor layer 6 in the RAM cell.

(3) A portion of the RAM cell where the second gate insulating layer 9 is provided is occupied by the memory layer 9b formed by the tunnel insulating layer 9b1, the signal charge storage layer 9b2, and the insulating layer 9b3 in the ROM cell.

Other than the above description, the basic structures of the RAM cell, the N-channel MOS transistor, and the ROM cell are substantially the same.

Three MOS transistors respectively formed in the pillar-shaped Players 3b, 3ba, and 3bb illustrated in FIGS. 4AA, 4AB, and 4AC have the same planar structure or fin structure. Alternatively, the MOS transistors illustrated in FIGS. 4AA and 4AC may be of the planar type, and the MOS transistor illustrated in FIG. 4AB may be of the fin type. In the planar structure, the second gate conductor layer 10, the third gate conductor layer 10a, and the fourth gate conductor layer 10b are formed so as to respectively cover the upper surfaces of the pillar-shaped Players 3, 3A, and 3B in the vertical direction. In the fin structure, the gate conductor layers are formed so as to cover the upper surfaces and the side surfaces of the pillar-shaped Players.

According to the present embodiment, the following features are obtained.

(1) The pillar-shaped Player 3b of the RAM cell, the pillar-shaped Player 3ba of the MOS transistor of the logic circuit, and the pillar-shaped Player 3bb of the ROM cell are formed so that the positions of the upper surfaces thereof are at the same height in the vertical direction. This feature contributes to simplification of the manufacturing steps of a semiconductor device including the RAM cell, the N-channel MOS transistor of the logic circuit, and the ROM cell formed in the pillar-shaped Players 3, 3A, and 3B on the P layer substrates 1, 1a, and 1b continuous with each other.

(2) Also, the pillar-shaped P layer 3b of the RAM cell, the pillar-shaped Player 3ba of the MOS transistor of the logic circuit, and the pillar-shaped Player 3bb of the ROM cell are formed so that the positions of bottom portions thereof are at the same height. Thus, the RAM cell, the N-channel MOS transistor, and the MOS transistor of the ROM cell are formed so as to have the same height in the vertical direction. This feature contributes to further simplification of the manufacturing steps of the semiconductor device.

(3) Also, the pillar-shaped Player 3 of the RAM cell, the pillar-shaped Player 3A of the MOS transistor of the logic circuit, and the pillar-shaped Player 3B of the ROM cell are formed so that the positions of the bottom portions thereof are at the same height. This feature contributes to further simplification of the manufacturing steps of the RAM cell, the N-channel MOS transistor, and the MOS transistor of the ROM cell.

Referring to FIGS. 4BA to 4BC, structures of the RAM cell, the N-channel MOS transistor of the logic circuit, and the ROM cell according to the present embodiment formed on the same substrate are described. FIG. 4BA illustrates the sectional structure of the RAM cell. FIG. 4BB illustrates the sectional structure of the N-channel MOS transistor of the logic circuit formed on the same substrate as that of the RAM cell. FIG. 4BC illustrates the sectional structure of the ROM cell formed on the same substrate as that of the RAM cell. In FIGS. 4BA to 4BC, the same structural portions as those of FIGS. 4AA to 4AC are denoted by the same reference numerals.

The sectional structure of the RAM cell illustrated in FIG. 4BA is the same as that illustrated in FIG. 4AA. In FIG. 4BB, the insulating layer 13a illustrated in the FIG. 4AB is replaced with a conductor layer 15a. In addition, an N⁺ layer 2a is provided on the Player substrate 1a so as to be continuous with the bottom portion of the pillar-shaped Player 3A. The N⁺ layer 2a is connected to a control line CL1. The conductor layer 15a is connected to a first back-gate line BG1. In FIG. 4BC, the insulating layer 13b illustrated in the FIG. 4AC is replaced with a conductor layer 15b. In addition, an N⁺ layer 2b is provided on the Player substrate 1b so as to be continuous with the bottom portion of the pillar-shaped P layer 3B. The N⁺ layer 2b is connected to a control line CL2. The conductor layer 15b is connected to a second back-gate line BG2.

A voltage applied to the first back-gate line BG1 is controlled so as to control a voltage of a base of the pillar-shaped Player 3aa. Thus, a threshold voltage of the MOS transistor including the pillar-shaped P layer 3ba provided on the pillar-shaped Player 3aa, the third gate insulating layer 9a, the third gate conductor layer 10a, and the N⁺ layers 11aa and 11ba is changed. In this way, the threshold voltage of each of a plurality of MOS transistors provided in the logic circuit is arbitrarily set by changing the voltage applied to the first back-gate line BG1. Likewise, a voltage applied to the second back-gate line BG2 is controlled so as to control a voltage of a base of the pillar-shaped Player 3ab. Thus, a threshold voltage of the MOS transistor including the pillar-shaped Player 3bb provided on the pillar-shaped Player 3ab, the memory layer 9b, the fourth gate conductor layer 10b, and the N⁺ layers 11ab and 11bb can be changed.

Referring to FIGS. 4BA to 4BC, the RAM cell, the MOS transistor, and the ROM cell having the same basic structures are formed. However, for one of the MOS transistor and the ROM cell, the structure illustrated in FIG. 4AB or 4AC may be used. Also with this structure, the manufacturing steps are the same as those for the case of FIG. 4AB or 4AC. In this case, the bottom portions of the pillar-shaped Players 3, 3A, and 3B are coincident with each other at line A, the positions of the top portions of the pillar-shaped P layers 3, 3A, and 3B are coincident with each other at line C, and the top portions of the pillar-shaped Players 3a, 3aa, and 3ab are coincident with each other at line B. Thus, a method for manufacturing can be simplified.

According to the present embodiment, the following features can be obtained.

(1) In the actual logic circuit, the MOS transistor having a plurality of threshold voltages is formed. The threshold voltage is varied by, for example, a method using a metal layer of a varied work function for the third gate conductor layer 10a, varying the concentration of the impurity of the pillar-shaped Player 3ba, or the like. In contrast, the threshold voltages can be set by using the same basic structures for the MOS transistor of the logic circuit and the memory cells without, for example, using a metal layer of a varied work function for the third gate conductor layer 10a or varying the concentration of the impurity of the pillar-shaped Player 3ba. Likewise, in the ROM cell, the threshold voltage for reading from the ROM cell can be varied by using the voltage applied to the back-gate line BG2. For example, drive operations of the RAM, the MOS transistor, and the ROM can be optimized by making the concentrations of the acceptor impurity of the pillar-shaped Players 3, 3A, and 3B in the RAM, the MOS transistor, and the ROM to be the same. Thus, the method for manufacturing can be simplified, and the cost of the memory device can be reduced.

(2) The basic structures of the RAM cell, the MOS transistor, and the ROM cell can be made to be the same. Thus, the manufacturing steps are simplified, and thereby the cost of the present semiconductor device is reduced.

Referring to FIGS. 5AA to 5IC, steps of forming the RAM cell, the N-channel MOS transistor of the logic circuit, and the ROM cell on the same substrate are described. FIG. 5AA illustrates the sectional structure of the RAM cell, FIG. 5AB illustrates the sectional structure of the N-channel MOS transistor of the logic circuit formed on the same substrate as that of the RAM cell, and FIG. 5AC illustrates the sectional structure of the ROM cell formed on the same substrate as that of the RAM cell. Although the distances and the positional relationships between the three structures in the horizontal direction are arbitrary in the FIGS. 5AA to 5AC, the positional relationships in the height direction are as illustrated in FIGS. 5AA to 5AC.

As illustrated in FIGS. 5AA to 5AC, in the RAM cell illustrated in FIG. 5AA, an N⁺ layer 22 is formed so as to overlie a Player substrate 20. In the N-channel MOS transistor illustrated in FIG. 5AB, a Player substrate 21a is provided so that the Player substrate 21a is continuous with the Player substrate 20 illustrated in FIG. 5AA and the position of a surface of the Player substrate 21a is coincident with the position of an upper surface of the N⁺ layer 22 at line A′. In the ROM cell illustrated in FIG. 5AC, a Player substrate 21b is provided so that the Player substrate 21b is connected to the Player substrate 20 illustrated in FIG. 5AA and the position of a surface of the Player substrate 21b is coincident with the position of the upper surface of the N⁺ layer 22 at line A′. The N⁺ layer 22 is formed with, for example, ion implantation to the Player substrate 20, plasma impurity doping, or an epitaxial crystal growth method. In the epitaxial crystal growth method, the Player substrate 20 is etched to a predetermined depth, and after that, for example, the following steps are performed: the epitaxial crystal growth of the semiconductor layer including the donor impurity; and surface chemical mechanical polishing (CMP) to align the positions of surfaces of the RAM cell, the N-channel MOS transistor, and the ROM cell.

Next, as illustrated in FIGS. 5BA to 5BC, Players 23a, 23b, and 23c are simultaneously formed on the N⁺ layer 22, the Player substrates 21a and 21b, respectively, with, for example, the epitaxial crystal growth method. A mask material layer 24a, a mask material layer 24b, and a mask material layer 24c are formed on the Player 23a, the P layer 23b, and the Player 23c, respectively. When the concentration of the acceptor impurity of the Players 23a, 23b, and 23c is changed, for example, ion implantation is performed under the conditions that are varied on a region-by-region basis.

Next, as illustrated in FIGS. 5CA to 5CC, the Players 23a, 23b, and 23c are etched, with, for example, a reactive ion etching (RIE) method, by using the mask material layers 24a, 24b, and 24c as masks so that the positions of a bottom portions of the etching are aligned with line A′. Thus, pillar-shaped Players 25a, 25b, and 25c having a rectangular shape in plan view and a pillar shape in vertical section are formed. In the RAM, etching is performed so that the bottom portion of the etching reaches an upper portion of an N⁺ layer 22a. Thus, the position of a surface of the N⁺ layer 22 at an outer peripheral portion of the pillar-shaped Player 25a in the RAM, the position of a surface of an outer peripheral portion of the pillar-shaped Player 25b in the MOS transistor, and the position of a surface of an outer peripheral portion of the pillar-shaped Player 25c in the ROM are substantially aligned with the height of line A′. The positions of upper surfaces of top portions of the pillar-shaped Player 25a, the pillar-shaped Player 25b, and the pillar-shaped Player 25c are substantially the same at the height of line C. In the actual RIE etching, the RIE etching rates at the N⁺ layer 22 and the Player substrates 21a and 21b are different from each other due to, for example, the difference in concentration of the impurity or the difference in location in the Player substrates 20, 21a, and the 21b. Accordingly, although a slight difference of the positions of upper surfaces in the vertical direction is produced between the N⁺ layer 22a, the Player substrate 21a, and the Player substrate 21b, these positions are substantially the same at the height of line A′. To vary the positions of bottom portions of the pillar-shaped Players 25a, 25b, and 25c, any of a RAM region, a MOS transistor region, and a ROM region is covered with the mask material layer to etch each of the pillar-shaped Players 25a, 25b, and 25c separately, and thereby the pillar-shaped Players 25a, 25b, and 25c are formed.

Next, as illustrated in FIGS. 5DA to 5DC, the N⁺ layer 22, surface layers of the P layer substrates 21a and 21b, and exposed portions of the pillar-shaped Players 25a, 25b, and 25c are oxidized to form oxidized insulating layers 27a, 27b, and 27c. The position of a surface of the N⁺ layer 22 at the outer peripheral portion of the pillar-shaped Player 25a in the RAM, the position of the surface of the outer peripheral portion of the pillar-shaped Player 25b in the MOS transistor, and the position of the surface of the outer peripheral portion of the pillar-shaped Player 25c in the ROM are substantially aligned with the height of line A. In the actual oxidization, the oxidization rates at the N⁺ layer 22 and the Player substrates 21a and 21b are different from each other due to, for example, the difference in concentration of the impurity or the difference in location in the Player substrates 20, 21a, and the 21b. Accordingly, although a slight difference of the positions of the upper surfaces in the vertical direction is produced between the N⁺ layer 22, the P layer substrate 21a, and the Player substrate 21b, these positions are substantially the same at the height of line A. The oxidized insulating layer 27a, 27b, and 27c may be formed with another method such as, for example, atomic layer deposition (ALD). In this case, the positions of the upper surfaces of the N⁺ layer 22 and the Player substrates 21a and 21b in the vertical direction are at line A′ without changes. Furthermore, formation of the oxidized insulating layers 27a, 27b, and 27c on outer peripheral portions and formation of the oxidized insulating layers 27a, 27b, and 27c on side surfaces may be separately performed for the pillar-shaped Players 25a, 25b, and 25c.

Next, as illustrated in FIGS. 5EA, 5EB, and 5EC, poly-Si layers 29a, 29b, and 29c including, for example, a large amount of the donor impurity or acceptor impurity are formed so as to surround lower portions of the oxidized insulating layers 27a, 27b, and 27c in portions covering the pillar-shaped Players 25a, 25b, and 25c. Insulating layers 30a, 30b, and 30c are formed on the poly-Si layers 29a, 29b, and 29c. Thus, the positions of surfaces of the insulating layers 30a, 30b, and 30c are substantially the same at the height of line B. The insulating layers 30a, 30b, and 30c may be formed with another method such as oxidization of the poly-Si layers 29a, 29b, and 29c. As a result, even when the positions of bottom portions of the pillar-shaped Players 25a, 25b, and 25c are different from each other, the positions of the surfaces of the insulating layers 30a, 30b, and 30c are substantially the same at the height of line B.

Next, as illustrated in FIGS. 5FA to 5FC, the poly-Si layer 29b of the MOS transistor and the poly-Si layer 29c of the ROM cell are discharged. Insulating layers 32a and 32b of SiO₂ or the like are formed with, for example, a chemical vapor deposition (CVD) method in spaces formed by discharging the poly-Si layers 29b, and 29c. The insulating layers 32a and 32b may be formed by other insulative material layers than SiO₂.

Next, as illustrated in FIGS. 5GA to 5GC, the exposed oxidized insulating layers 27a, 27b, and 27c are etched to form oxidized insulating layers 27aa, 27ba, and 27ca. The mask material layers 24a, 24b, and 24c are discharged. A second gate insulating layer 32a, a third gate insulating layer 32b, and a memory layer 32c are formed so as to cover the upper surfaces of the top portions or the exposed upper surfaces and side surfaces of the pillar-shaped P layer 25a, 25b, 25c. As extracted and illustrated at the upper portion of FIG. 5GC, the memory layer 32c is formed by a tunnel insulating layer 32cl, a signal charge storage layer 32c2, and an insulating layer 32c3 from below. A second gate conductor layer 33a, a third gate conductor layer 33b, and a fourth gate conductor layer 33c are formed. When planar-type MOS transistors are formed on the upper side of the pillar-shaped Players 25a, 25b, and 25c, the first to third gate insulating layers 32a to 32c and the second to fourth gate conductor layers 33a to 33c are formed on the upper surfaces of the pillar-shaped Players 25a, 25b, and 25c in the vertical direction. When fin-type MOS transistors are formed on the upper side of the pillar-shaped Players 25a, 25b, and 25c, the first to third gate insulating layers 32a to 32c and the second to fourth gate conductor layers 33a to 33c are formed on the upper surface in the vertical direction and both side surfaces of each of the pillar-shaped Players 25a, 25b, and 25c in the vertical direction. The second gate conductor layer 33a, the third gate conductor layer 33b, the fourth gate conductor layer 33c may be formed with a method such as, for example, a gate-first method or a gate-last method (see, for example, Martin M. Frank, “High-k/Metal Gate Innovations Enabling Continued CMOS Scaling” Proc. of the 41th European Solid-state Device Research Conference pp. 50-58(2011)).

Next, as illustrated in FIG. 5HA, N⁺ layers 35a and 35b are formed at either end of the top portion of the pillar-shaped Player 25a in the page of FIG. 5HA on the insulating layer 30a. Likewise, as illustrated in FIG. 5HB, N⁺ layers 35aa and 35ba are formed at either end of the top portion of the pillar-shaped Player 25b in the page of FIG. 5HB on the insulating layer 30b. Likewise, as illustrated in FIG. 5HC, N⁺ layers 35ab and 35bb are formed at either end of the top portion of the pillar-shaped Player 25c in the page of FIG. 5HC on the insulating layer 30c. The N⁺ layer 35a, 35b, 35aa, 35ba, 35ab, or 35bb is not formed at the front or back of the upper portion of the pillar-shaped Player 25a, 25b, or 25c of the pages of FIGS. 5HA to 5HC. Lightly-doped drain (LDD) regions may be formed between the pillar-shaped Player 25a and the N⁺ layers 35a and 35b, between the pillar-shaped P layer 25b and the N⁺ layers 35aa and 35ba, and between the pillar-shaped P layer 25c and the N⁺ layers 35ab and 35bb.

Next, as illustrated in FIGS. 5IA to 5IC, the entire structures are covered by insulating layers 37, 37a, and 37b. The following wiring layers are formed: a wiring layer 38 connected to the N⁺ layer 35a; a wiring layer 39 connected to the second gate conductor layer 33a; a wiring layer 40 connected to the N⁺ layer 35b; a wiring layer 41a connected to the N⁺ layer 35aa; a wiring layer 42a connected to the third gate conductor layer 33b; a wiring layer 43a connected to the N⁺ layer 35ba; a wiring layer 41b connected to the N⁺ layer 35ab; a wiring layer 42b connected to the fourth gate conductor layer 33c; and a wiring layer 43b connected to the N⁺ layer 35bb. The wiring layer 38 is connected to the first source line SL1, the wiring layer 39 is connected to the first word line WL1, and the wiring layer 40 is connected to the first bit line BL1. The wiring layer 41a is connected to the source line S, the wiring layer 42a is connected to the gate line G, and the wiring layer 43a is connected to the drain line D. The wiring layer 41b is connected to the second source line SL2, the wiring layer 42b is connected to the second word line WL2, and the wiring layer 43b is connected to the second bit line BL2. The poly-Si layer 29a is connected to the plate line PL. Thus, the RAM cell, the N-channel MOS transistor, and the ROM cell are formed on the Player substrates 20, 21a, and 21b continuous with each other.

The method for manufacturing the N-channel MOS transistor of a logic circuit region has been described with reference to FIGS. 5AA to 5IC. In the actual logic circuit region, a P-channel MOS transistor is also formed on the same Player substrate 21a. In the P-channel MOS transistor, the N⁺ layers 35aa and 35ba of the N-channel MOS transistor are replaced with a P⁺ layer including many acceptor impurities, and the materials, dimensions, and the like of the gate insulating layer 32b and the third gate conductor layer 33b may be changed according to design requests. However, the basic structure of the P-channel MOS transistor is the same as that of the MOS transistor. The height of the position of a bottom portion of a semiconductor pillar corresponding to the pillar-shaped Player 25b in which the P-channel MOS transistor is formed is substantially aligned with line A, and the height of the position of a top portion of the semiconductor pillar is substantially aligned with line C. The height of a bottom portion of the P-channel MOS transistor is, as is the case with the bottom portion of the N-channel MOS transistor, substantially aligned with line B. A Player of a low acceptor concentration may be used for an N layer of the pillar-shaped semiconductor layer of the P-channel MOS transistor. A well structure, shallow trench isolation (STI), and the like are used for electrical isolation between the N-channel MOS transistor and the P-channel MOS transistor.

When the MOS transistors of the RAM cell and the ROM cell are formed as the planar type and the MOS transistor of the logic circuit is formed as the fin type, upper surfaces of the Players 23a and 23c are etched before the formation of the mask material layers 24a, 24b, and 24c in FIGS. 5BA to 5BC so as to set the positions of the upper surfaces of the Players 23a and 23c to be lower than the upper surface of the Player 23b. In this case, the thickness of the mask material layers 24a and 24c are greater than the thickness of the mask material layer 24b. Thus, the pillar-shaped Players 25a and 25c of the MOS transistors of the RAM cell and the ROM cell can be formed so that the positions of the top portions of the pillar-shaped Players 25a and 25c are lower than the position of the top portion of the pillar-shaped Player 25b of the MOS transistor of the logic circuit.

Furthermore, in the vertical direction, the position of a boundary between the N⁺ layer 22 and the pillar-shaped Player 25a may be higher than or lower than the position of a bottom surface of a first gate conductor layer 29a.

The pillar-shaped Players 25a, 25b, and 25c may be each formed as follows: a material layer to be served as the first gate conductor layer 29a and insulating layers on the upper and lower sides of the material layer are deposited in layers; then, a hole extending through these layers is formed; and form the pillar-shaped Player with, for example, a selective crystal epitaxial method or a metal induced lateral crystallization (MILC) method (see, for example, H. Miyagawa et al. “Metal-Assisted Solid-Phase Crystallization Process for Vertical Monocrystalline Si Channel in 3D Flash Memory”, IEDM19 digest paper, pp. 650-653 (2019)). The first gate conductor layer 29a may be formed by etching a dummy gate material that has been formed first, and then, embedding the first gate conductor layer 29a into a space formed by the etching.

The method for manufacturing according to the present embodiment illustrated in FIGS. 5AA to 5IC has the following features.

(1) As illustrated in FIGS. 5BA to 5BC and 5CA to 5CC, the pillar-shaped Player 25a including the upper portion of the N⁺ layer 22 being part of the RAM cell, the pillar-shaped Player 25b of the MOS transistor, and the pillar-shaped Player 25c of the ROM cell are formed by simultaneously etching the Players 23a, 23b, and 23c with the mask material layers 24a, 24b, and 24c used as etching masks. Thus, the pillar-shaped Player 25a including the upper portion of the N⁺ layer 22, the pillar-shaped Player 25b, and the pillar-shaped P layer 25c can be formed so that the positions of bottom surfaces of these pillar-shaped Players 25a, 25b, and 25c are the same at line A′, and the positions of the top portions of these pillar-shaped Players 25a, 25b, and 25c are the same at line C. After that, the steps are performed with reference to the pillar-shaped Players 25a, 25b, and 25c. Thus, the steps are simplified.

(2) Except for the forming steps of the first gate conductor layer 29a of the RAM cell and the insulating layers 32a and 32b of the MOS transistor and the ROM cell, many steps before and after these steps can be the same. Thus, steps are simplified.

(3) Referring to FIG. 5EA to 5EC, since the positions of the upper surfaces of the insulating layers 30a, 30b, and 30c are coincident with each other at line B, the commonality of many following steps of forming the MOS transistors of the RAM cell, the logic circuit, and the ROM cell can be achieved.

The Player substrate 1 illustrated in FIG. 1 may be a semiconductor or an insulating layer. Alternatively, the Player substrate 1 may be a well layer. This is similarly applied to other embodiments.

Referring to FIG. 1, the combination of the first gate conductor layer 6 and the second gate conductor layer 10 may be a combination in which the work function of the first gate conductor layer 6 is greater than the work function of the second gate conductor layer 10 such as, for example, P⁺ poly (5.15 eV)/a laminated structure of W and TIN (4.7 eV), P⁺ poly (5.15 eV)/a laminated structure of silicide and N⁺ poly (4.05 eV), or TaN (5.43 eV)/a laminated structure of W and TiN (4.7 eV). In the case where an N-type semiconductor is used for the pillar-shaped Player 3, when the work function of the first gate conductor layer 6 is smaller than the work function of the second gate conductor layer 10, for example, N⁺ poly is used for the first gate conductor layer 6 and P⁺ poly is used for the second gate conductor layer 10, a similar effect can be obtained. The first gate conductor layer 6 and the second gate conductor layer 10 may be semiconductors, metal, or chemical compounds of a semiconductor and metal. This is similarly applied to other examples.

The vertical sectional shape of the pillar-shaped Player 3 illustrated in FIG. 1 is a rectangular shape in the above description. However, the vertical sectional shape of the pillar-shaped Player 3 may be a trapezoidal shape. This is similarly applied to the other embodiments. The horizontal section of the pillar-shaped Player 3 may be a square shape or a rectangular shape. This is similarly applied to the other examples.

Referring to FIG. 1, the N⁺ layer 2 is drawn such that the N⁺ layer 2 is continuous with the adjacent memory cells. However, the N⁺ layer 2 may be provided only at the bottom portion of the pillar-shaped Player 3. In this case, the N⁺ layer 2 is not necessarily connected to the control line CL or may be extended in a direction perpendicular to a direction in which the N⁺ layer 2 is continuous with the N⁺ layers 11a and 11b in plan view so as to allow the control line CL to be connected to the extended portion of the N⁺ layer 2. Also in these cases, a normal memory operation can be performed. This is similarly applied to the other examples.

In the case where the N⁺ layer 2 illustrated in FIG. 1 is continuous with the adjacent memory cells and connected to the control line CL, a conductor layer may be provided in part or the entirety of the N⁺ layer 2 at the outer peripheral portion of the pillar-shaped Player 3 in plan view. This is similarly applied to the other examples.

Each of the insulating layer 9b1, the signal charge storage layer 9b2, and the insulating layer 9b3 included in the memory layer 9b illustrated in FIG. 4AC may be formed by a single layer or a plurality of different material layers. This is similarly applied to the other examples.

The N⁺ layer 35a of the RAM cell connected to the first source line SL1 illustrated in FIG. 5IA may be shared between cells adjacent to each other. Also, the N⁺ layer 35b connected to the first bit line BL1 may be shared between cells adjacent to each other. In this way, the RAM region is highly integrated. This is similarly applied to the other examples.

Referring to FIG. 1, the first gate conductor layer 6 and the second gate conductor layer 10 may be divided, in the horizontal or vertical direction, into plurality of pieces that are to be driven in a synchronous manner or an asynchronous manner. Also in this case, a normal memory operation is performed. Referring to FIGS. 4BA to 4BC, the first gate conductor layer 6 and the conductor layers 15a and 15b may be divided in the horizontal or vertical direction as is the case with the divided first gate conductor layer 6. This is similarly applied to the other examples.

An SOI substrate or a substrate of a well structure or the like may be used for the Player substrate 1 illustrated in FIG. 1. A MOS transistor circuit isolated by the insulating layer may be provided below the N⁺ layer 2. This is similarly applied to the other examples.

Referring to FIGS. 5AA to 5IC, the pillar-shaped Players 25a, 25b, and 25c are formed by etching the Players 23a, 23b, and 23c with the mask material layers 24a, 24b, and 24c as the etching masks. In contrast, the pillar-shaped Players 25a, 25b, and 25c may be formed, for example, as follows: a poly-Si layer that is interposed between insulating layers in the up-down direction and continues entirely in the horizontal direction is formed; holes are formed in the poly-Si layer; oxidized insulating layers 27a, 27b, and 27c are formed on side surfaces of the holes; and after that, the pillar-shaped P layers 25a, 25b, and 25c are formed with an epitaxial crystal growth method. This is similarly applied to the other examples.

In addition, various embodiments and modifications of the present invention can be made without departing from the broad spirit and scope of the present invention. Each of the embodiments described above is for describing an example of the present invention and does not limit the scope of the present invention. The above-described examples and modifications can be arbitrarily combined with each other. Furthermore, embodiments from which a subset of constituent features of the embodiments are removed according to necessity also fall within the technical idea of the present invention.

With the semiconductor device including the memory elements according to the present invention, a high-performance low-cost semiconductor device can be provided.

What is claimed is:

1. A semiconductor device including memory elements, the device comprising:
a first memory element;
a metal oxide semiconductor transistor; and
a second memory element, wherein
the first memory element includes
a first semiconductor pillar that stands erect on a substrate in a vertical direction with respect to the substrate,
a first impurity region continuous with a bottom portion of the first semiconductor pillar,
a first gate insulating layer in contact with a lower portion of the first semiconductor pillar,
a first gate conductor layer in contact with part of or an entirety of the first gate insulating layer,
a first insulating layer that is provided on the first gate conductor layer and that surrounds the first semiconductor pillar,
a second gate insulating layer that is, in the vertical direction, in contact with an upper surface of the first semiconductor pillar above the first gate insulating layer or in contact with the upper surface and both side surfaces continuous with the upper surface,
a second gate conductor layer that covers the second gate insulating layer, and
a second impurity region and a third impurity region provided at either end, in a horizontal direction, of part of the first semiconductor pillar that is not covered with the second gate insulating layer, wherein
the metal oxide semiconductor transistor includes
a second semiconductor pillar that stands erect on the substrate in the vertical direction with respect to the substrate,
a first material layer that is made of an insulative material or a conductive material and that is in contact with a lower portion of the second semiconductor pillar,
a third gate insulating layer that covers, in the vertical direction, an upper surface of the second semiconductor pillar above the first material layer or that covers the upper surface and both side surfaces of the second semiconductor pillar which face each other,
a third gate conductor layer that covers the third gate insulating layer, and
a fourth impurity region and a fifth impurity region provided at either end, in the horizontal direction, of part of the second semiconductor pillar that is not covered with the third gate insulating layer, wherein
the second memory element includes
a third semiconductor pillar that stands erect on the substrate in the vertical direction with respect to the substrate,
a second material layer that includes an insulative material or that partly includes a conductive material and that surrounds a lower portion of the third semiconductor pillar,
a memory layer that includes a signal charge storage layer interposed between insulating layers and that covers, in the vertical direction, an upper surface of the third semiconductor pillar above the second material layer or that covers the upper surface and both side surfaces of the third semiconductor pillar that face each other,
a fourth gate conductor layer that covers the memory layer, and
a sixth impurity layer and a seventh impurity layer provided at either end, in the horizontal direction, of part of the third semiconductor pillar that is not covered with the signal charge storage layer, and wherein
a position of an upper surface of the first semiconductor pillar, a position of an upper surface of the second semiconductor pillar, and a position of an upper surface of the third semiconductor pillar are substantially aligned with each other in the vertical direction.

2. The semiconductor device including memory elements according to claim 1, wherein
a position of an upper surface of the first insulator layer, a position of an upper surface of the first material layer, and a position of an upper surface of the second material layer are substantially aligned with each other in the vertical direction.

3. The semiconductor device including memory elements according to claim 1, wherein
a position of a bottom portion of a first semiconductor layer, a position of a bottom portion of a second semiconductor layer, and a position of a bottom portion of a third semiconductor layer are substantially aligned with each other in the vertical direction.

4. The semiconductor device including memory elements according to claim 1, wherein
one or both of the first material layer and the second material layer are formed of an insulative material.

5. The semiconductor device including memory elements according to claim 1, wherein
one or both of the first material layer and the second material layer are formed of a conductive material.

6. The semiconductor device including memory elements according to claim 1, wherein
the signal charge storage layer is formed by a conductive layer of a semiconductor, metal, an alloy, or another conductor, or an insulating layer.

7. The semiconductor device including memory elements according to claim 1, wherein
a transistor including an upper portion of the first semiconductor pillar, the second gate insulating layer, the second gate conductor layer, the second impurity region, and the third impurity region of the first memory element is of a planar type,
a transistor including an upper portion of the second semiconductor pillar, the third gate insulating layer, the third gate conductor layer, the fourth impurity region, and the fifth impurity region of the metal oxide semiconductor transistor is of the planar type, and
a transistor including an upper portion of the third semiconductor pillar, the memory layer, the fourth gate conductor layer, the sixth impurity layer, and the seventh impurity layer of the second memory element is of the planar type.

8. The semiconductor device including memory elements according to claim 1, wherein
a transistor including an upper portion of the first semiconductor pillar, the second gate insulating layer, the second gate conductor layer, the second impurity region, and the third impurity region of the first memory element is of a planar type,
a transistor including an upper portion of the second semiconductor pillar, the third gate insulating layer, the third gate conductor layer, the fourth impurity region, and the fifth impurity region of the metal oxide semiconductor transistor is of a fin type, and
a transistor including an upper portion of the third semiconductor pillar, the signal charge storage layer, the fourth gate conductor layer, the sixth impurity layer, and the seventh impurity layer of the second memory element is of the planar type.

9. The semiconductor device including memory elements according to claim 1, wherein
the first impurity region is continuous with a bottom portion of a semiconductor pillar of another first memory element adjacent to the first semiconductor pillar.

10. The semiconductor device including memory elements according to claim 1, wherein
the first impurity region is separate from an impurity layer of a bottom portion of a semiconductor pillar of another first memory element adjacent to the first semiconductor pillar.

11. The semiconductor device including memory elements according to claim 1, wherein
an eighth impurity layer is provided at a bottom portion of one or each of the second semiconductor pillar and the third semiconductor pillar.

12. The semiconductor device including memory elements according to claim 1, wherein
the first gate conductor layer is divided into two conductor layers in one or both of the horizontal direction and the vertical direction, and the divided conductor layers are driven in a synchronous manner or in an asynchronous manner.

13. The semiconductor device including memory elements according to claim 1, wherein
the second impurity region, the third impurity region, the first gate conductor layer, and the second gate conductor layer are configured to perform a memory write operation and a memory erase operation, wherein,
in the memory write operation, voltages applied to the second impurity region, the third impurity region, the first gate conductor layer, and the second gate conductor layer are controlled so as to generate an electron group and a positive hole group in an upper portion of the first semiconductor pillar by using impact ionization caused by a current flowing between the first impurity region and the second impurity region or by using a gate-induced drain-leakage current, and
part or an entirety of the electron group or the positive hole group that is a majority carrier out of the generated electron group and the generated positive hole group is caused to remain in the first semiconductor pillar mainly surrounded by the first gate insulating layer, and wherein,
in the memory erase operation, the electron group or the positive hole group that is the majority carrier having been caused to remain is removed from a subset or all of the first impurity region, the second impurity region, and the third impurity region.
